(19) United States
(12) Patent Application Publication
(10) Pub. No.: US 2022/0066613 A1
(43) Pub. Date: Mar. 3, 2022

(54) TOUCH DISPLAY PANEL AND ELECTRONIC DEVICE

(71) Applicant: SHENZHEN ROYOLE TECHNOLOGIES CO., LTD., Shenzhen (CN)

(72) Inventors: Ze YUAN, Shenzhen (CN); Jiahao KANG, Shenzhen (CN); Haojun LUO, Shenzhen (CN); Wenbing HU, Shenzhen (CN)

(21) Appl. No.: 17/412,387

(22) Filed: Aug. 26, 2021

(30) Foreign Application Priority Data
Aug. 26, 2020 (CN) 202010872154.5

(51) Int. Cl. G06F 3/041; G06F 3/044; H01L 27/32; H01L 51/52

(52) U.S. Cl. CPC G06F 3/04184; G06F 3/0412; G06F 3/044; G06F 3/04164; G06F 2203/04107; H01L 27/3258; H01L 27/3272; H01L 27/3276; H01L 51/5253; H01L 27/323

(57) ABSTRACT

The present disclosure relates to a touch display panel and an electronic device. The touch display panel includes: a substrate; multiple display signal lines arranged on one side of the substrate to provide display signals; multiple touch induction electrodes arranged on one side of each of the display signal lines facing away from the substrate, stacked and arranged at intervals with the display signal lines, and the multiple touch induction electrodes and the multiple display signal lines have overlapped regions; and a shielding layer located between the touch induction electrodes and the display signal lines, at least a part located in the overlapped regions, and used to reduce signal interference between the touch induction electrodes and the display signal lines. Interference between display signals of the display signal lines and touch signals of the touch induction electrodes can be effectively prevent, and signal-to-noise ratio can be effectively increased.

### TECHNICAL FIELD

The present disclosure relates to the field of touch display, and in particular, to a touch display panel and an electronic device.

### BACKGROUND

An existing touch display panel is becoming more and more integrated.

With the improvement of integration of the touch display panel, the distance along the thickness direction between touch induction electrodes and display signal lines (such as scanning display signal lines and data display signal lines) on the touch display panel is very small. So, capacitance occurs between the touch induction electrodes and the scanning display signal lines, or between the touch induction electrodes and the data display signal lines, which results in capacitive crosstalk between display signals and touch drive signals of the touch display panel, and further reducing of a signal-to-noise ratio of the touch drive signals.

### SUMMARY

In view of this, it is necessary to provide a touch display panel, which can effectively prevent interference between display signals of the display signal lines and touch signals of touch induction electrodes, and increase a signal-to-noise ratio of the touch display panel.

In addition, it is necessary to provide an electronic device.

An embodiment of the present disclosure provides a touch display panel, including:

a substrate;

multiple display signal lines arranged on one side of the substrate, where the display signal lines are configured to provide display signals;

multiple light-emitting units, where the multiple light-emitting units are arranged at a same layer and arranged in an array on one side of the display signal lines that faces away from the substrate;

multiple touch induction electrodes, where the multiple touch induction electrodes are arranged on one side of the light-emitting units that faces away from the substrate, the touch induction electrodes and the display signal lines are stacked and arranged at intervals, and the multiple touch induction electrodes and the multiple display signal lines have overlapped regions; and

a shielding layer, where the shielding layer is located between the touch induction electrodes and the display signal lines, at least a part of the shielding layer is located in the overlapped regions, and the shielding layer is configured to reduce signal interference between the touch induction electrodes and the display signal lines.

Further, the display signal lines comprise at least one of a scanning display signal line and a data display signal line.

Further, the shielding layer is loaded with a constant voltage signal or grounded.

Further, the shielding layer is loaded with a signal the same as that of the touch induction electrode.

Further, the touch display panel further includes a touch signal line, where the touch signal line is electrically connected to the touch induction electrode and the shielding layer.

Further, the light-emitting units each include an anode, and the shielding layer and the anode are arranged at an interval at a same layer.

Further, the shielding layer is insulated from the anode, and the shielding layer and the anode are formed in a same process.

Further, the light-emitting units each include an anode; and the shielding layer is located between the anode and the display signal line.

Further, the light-emitting units each further include a cathode, and the cathode is located between the touch induction electrode and the anode.

Further, the touch display panel further includes an encapsulation layer, where the encapsulation layer is located on one side of each of the light-emitting units that faces away from the substrate, and the touch induction electrodes each are located on a surface of the encapsulation layer that faces away from the light-emitting unit.

Further, the light-emitting units each further include a cathode, the cathode includes multiple sub-cathodes arranged at intervals, and a gap is formed between adjacent sub-cathodes; the cathode and each of the touch induction electrodes are arranged at a same layer and insulated from each other; and the touch induction electrode is located in the gap.

Further, the light-emitting units each further include a cathode, the cathode includes multiple sub-cathodes arranged at intervals, and each of the touch induction electrodes is formed by electrically connecting several sub-cathodes.

Further, the touch display panel includes a drive circuit, where the drive circuit is arranged between the substrate and the multiple touch induction electrodes; the drive circuit includes a source/drain electrode, and the shielding layer and the source/drain electrode are arranged at a same layer and insulated from each other.

Further, the touch display panel further includes a drive circuit and light-emitting units, where the drive circuit and the light-emitting units are stacked between the substrate and the multiple touch induction electrodes, and the drive circuit is adjacent to the substrate; the light-emitting units each include an anode; the drive circuit includes a source/drain electrode and a metal wire; the metal wire is located between the source/drain electrode and the anode and electrically connected to the source/drain electrode and the anode; and the shielding layer and the metal wire are arranged at a same layer and insulated from each other.

Further, the shielding layer and the metal wire are formed in a same process.

Further, an insulating layer and a planarization layer are sequentially stacked on one side of the source/drain electrode that faces away from the substrate; the metal wire and the shielding layer are located on a surface of the planarization layer that faces away from the substrate; the insulating layer and the planarization layer are provided with a through hole that runs through the insulating layer and the planarization layer, and the through hole is filled with a material the same as that of the metal wire to electrically connect the metal wire to the source/drain electrode.

Further, the shielding layer includes multiple shielding units, the multiple shielding units are connected into a whole, and the shielding layer at least partially overlaps with the overlapped regions.

Further, the shielding layer includes multiple shielding units arranged at intervals, and each of the shielding units at least partially overlaps with at least one of the overlapped regions.

Further, the multiple shielding units are arranged at a same layer or at different layers.

An embodiment of the present disclosure further provides an electronic device, including:

a device body; and

the above-mentioned touch display panel, where the touch display panel is arranged on the device body and configured to implement display and touch functions.

Therefore, in this disclosure, the shielding layer is provided between the display signal lines and the touch induction electrodes, which effectively prevents the interference between display signals of the display signal lines and touch signals of the touch induction electrodes, when the display signal lines overlap with the touch induction electrodes. So, signal-to-noise ratio of the touch display panel is further increased.

### BRIEF DESCRIPTION OF DRAWINGS

To illustrate structural features and functions of the present disclosure more clearly, the following detailed description will be made with reference to the accompanying drawings and specific embodiments.

FIG. 1 is a schematic structural diagram illustrating a touch display panel according to an embodiment of the present disclosure;

FIG. 2 is a schematic structural diagram illustrating a touch display panel according to another embodiment of the present disclosure;

FIG. 3 is a schematic structural diagram illustrating a touch display panel according to another embodiment of the present disclosure;

FIG. 4 is a schematic structural diagram illustrating a touch display panel according to another embodiment of the present disclosure;

FIG. 5 is a schematic structural diagram illustrating a touch display panel according to another embodiment of the present disclosure;

FIG. 6 is a schematic structural diagram illustrating a cathode and touch induction electrodes of a touch display panel according to an embodiment of the present disclosure;

FIG. 7 is a schematic structural diagram illustrating a cathode and touch induction electrodes of a touch display panel according to another embodiment of the present disclosure;

FIG. 8 is a schematic structural diagram illustrating a touch display panel according to another embodiment of the present disclosure; and

FIG. 9 is a schematic structural diagram illustrating an electronic device according to an embodiment of the present disclosure.

### DESCRIPTION OF EMBODIMENTS

The technical solutions in the embodiments of the present disclosure will be clearly and completely described below in conjunction with the accompanying drawings in the embodiments of the present disclosure. Apparently, the described embodiments are merely some rather than all of the embodiments of the present disclosure. All other embodiments obtained by a person of ordinary skill in the art based on the embodiments of the present disclosure without creative efforts shall fall within the protection scope of the present disclosure.

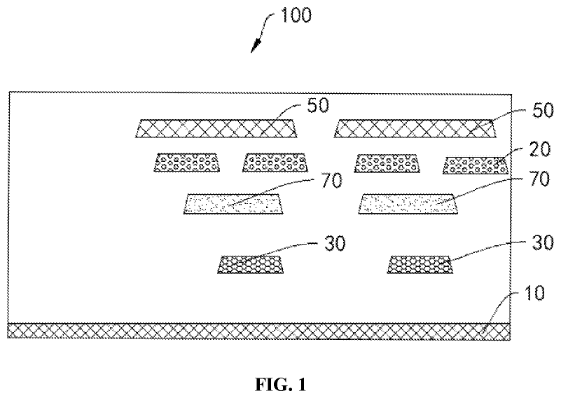

Referring to FIG. 1, an embodiment of the present disclosure provides a touch display panel 100, including: a substrate 10; multiple display signal lines 30 arranged on one side of the substrate 10, where the display signal lines 30 are configured to provide display signals; multiple touch induction electrodes 50, where the touch induction electrodes 50 are each configured to access a touch signal, the multiple touch induction electrodes 50 are arranged on one side of the display signal lines 30 that faces away from the substrate 10, the touch induction electrodes 50 and the display signal lines 30 are stacked and arranged at intervals, and the multiple touch induction electrodes 50 and the multiple display signal lines 30 have overlapped regions; and a shielding layer 70, where the shielding layer 70 is located between the touch induction electrodes 50 and the display signal lines 30, at least a part of the shielding layer 70 is located in the overlapped regions, and the shielding layer 70 is configured to reduce signal interference between the touch induction electrodes 50 and the display signal lines 30.

It should be understood that the touch display panel 100 according to the present disclosure may be a self-capacitive touch display panel or a mutual capacitive touch display panel. In addition, the touch display panel 100 may also be applied to other types of touch display panels integrating touch and display functions, which is not specifically limited in the present disclosure.

Optionally, the display signal lines 30 comprise at least one of a scanning display signal line and a data display signal line. The scanning display signal line is configured to access a display drive signal for the touch display panel 100, and the data display signal line is configured to access a display data signal for the touch display panel 100.

Optionally, in some embodiments, the shielding layer 70 is loaded with a constant voltage signal or grounded. When the shielding layer 70 is loaded with a constant voltage signal or grounded, interference of the display signal lines 30 to the touch induction electrodes 50 can be effectively shielded.

Optionally, in some embodiments, the shielding layer 70 is loaded with a signal the same as that of the touch induction electrodes 50. Specifically, the signal may be a touch drive signal loaded on the touch induction electrodes 50.

This can prevent capacitance from being formed between the shielding layer 70 and the touch induction electrodes 50, so as to further eliminate a capacitive load generated by the shielding layer 70 on the touch induction electrodes 50.

The touch display panel 100 according to the present disclosure is provided with the shielding layer 70 between the display signal lines 30 and the touch induction electrodes 50, which prevents interference between display signals of the display signal lines 30 and touch signals of the touch induction electrodes 50 when the display signal lines 30 overlap with the touch induction electrodes 50, and increases a signal-to-noise ratio of the touch display panel 100.

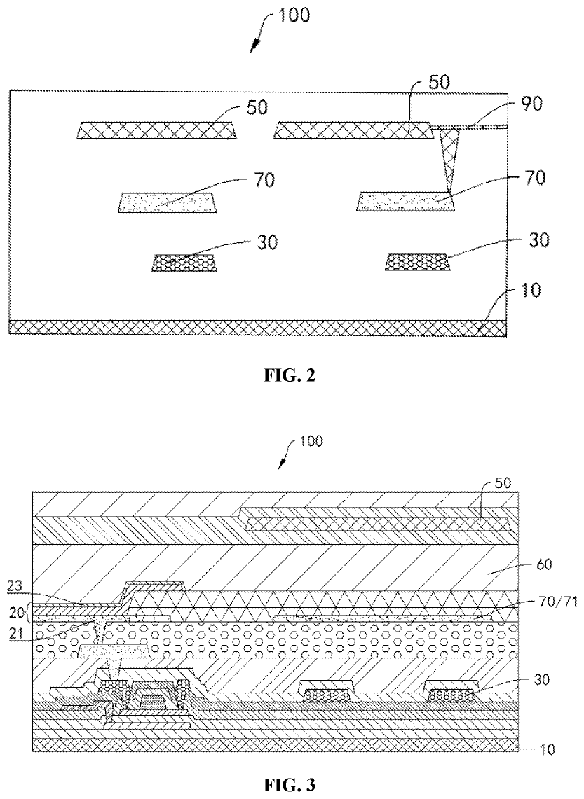

Referring to FIG. 2, optionally, in some embodiments, the touch display panel 100 further includes a touch signal line 90, where the touch signal line 90 is electrically connected to the touch induction electrode 50 and the shielding layer 70, respectively. Specifically, the touch signal line 90 may be electrically connected to the touch induction electrode 50 and the shielding layer 70 through via holes, respectively.

Referring to FIG. 3, in some embodiments, the touch display panel 100 according to the embodiments of the present disclosure further includes light-emitting units 20, where the light-emitting units 20 are arranged between multiple display signal lines 30 and multiple touch induction electrodes 50, and configured to provide a light source for the touch display panel 100. The light-emitting units 20 each include an anode 21, and the anode 21 is configured to be connected to a high level. The shielding layer 70 and the anode 21 are arranged at an interval at a same layer. Specifically, the shielding layer 70 is insulated from the anode 21, and the shielding layer 70 and the anode 21 are formed in a same process, i.e., an entire anode layer is prepared first, and then the anode layer is patterned by using an etching process to form the anode 21 and the shielding layer 70 that are insulated from each other.

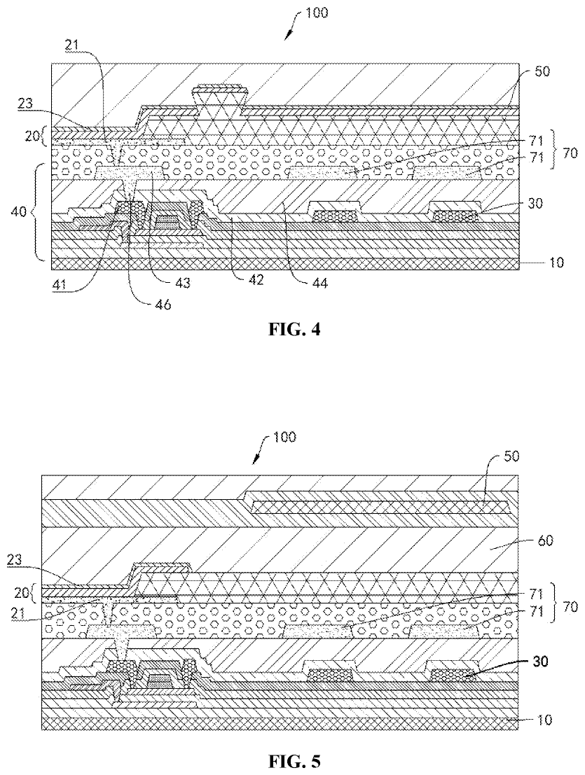

Referring to FIG. 4 and FIG. 5, in some other embodiments, the shielding layer 70 may alternatively be located between the anode 21 and the display signal lines 30. Specifically, a planarization layer is arranged on a surface of the anode 21 that faces away from the substrate 10, and the shielding layer 70 is located at the planarization layer. More specifically, the shielding layer 70 may be located at any position between the anode 21 and the display signal lines 30.

Referring to FIG. 3 and FIG. 5, in some embodiments, the light-emitting units 20 each further include a cathode 23, and the cathode 23 and the touch induction electrodes 50 are arranged at different layers and insulated from each other, i.e., the cathode 23 and the touch induction electrodes 50 are different electrodes. In this case, the cathode 23 is located between the touch induction electrodes 50 and the anode 21, and the cathode 23 is configured to be connected to a low level.

Referring to FIG. 3 and FIG. 5, in some embodiments, the touch display panel 100 according to the embodiments of the present disclosure further includes an encapsulation layer 60, where the encapsulation layer 60 is located on one side of each of the light-emitting units 20 that faces away from the substrate 10, and the touch induction electrodes 50 each are located on a surface of the encapsulation layer 60 that faces away from the light-emitting unit 20.

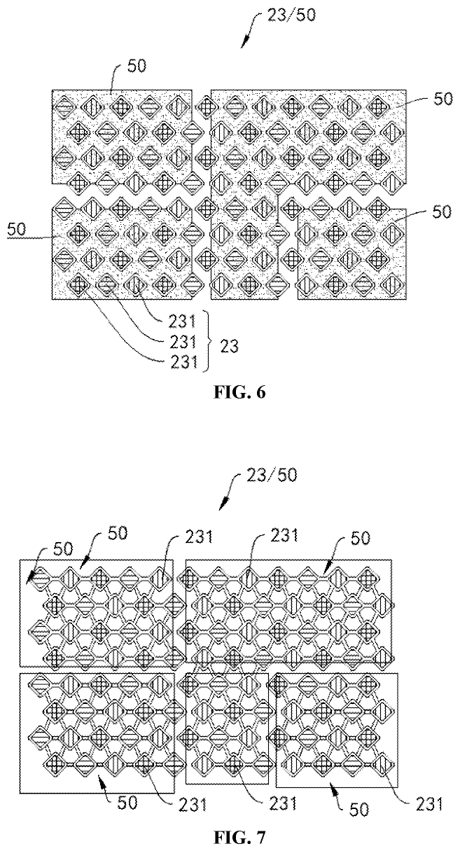

Referring to FIG. 6, in some embodiments, the light-emitting units 20 each further include a cathode 23, the cathode 23 includes multiple sub-cathodes 231 arranged at intervals, and a gap is formed between adjacent sub-cathodes 231; the cathode 23 and each of the touch induction electrodes 50 are arranged at a same layer and insulated from each other; and the touch induction electrode 50 is located in the gap. The cathode 23 and each of the touch induction electrodes 50 are arranged at the same layer and insulated from each other, which can further reduce a thickness of the touch display panel 100, and is beneficial to ultra-thinness of the touch display panel 100.

Referring to FIG. 7, in some embodiments, each touch induction electrode 50 is formed by several electrical-connected sub-cathodes 231. Since the touch induction electrode 50 and the cathode 23 share an electrode, a touch function and a display function of the touch display panel 100 may be controlled in a time division multiplexing manner That is, in one light-emitting period of the light-emitting unit 20, the touch induction electrode 50 accesses a touch drive signal in a part of the period, and accesses a display signal in the other part of the period. The light-emitting period of the light-emitting unit 20 includes a reset phase, a write-in phase and a light-emitting phase. During the reset phase and the write-in phase, the cathode 23 does not require a fixed voltage. Therefore, the cathode 23 may access a touch drive signal in part of time of the reset phase and the write-in phase, and the cathode 23 may access a display drive signal in other time periods, such as grounding.

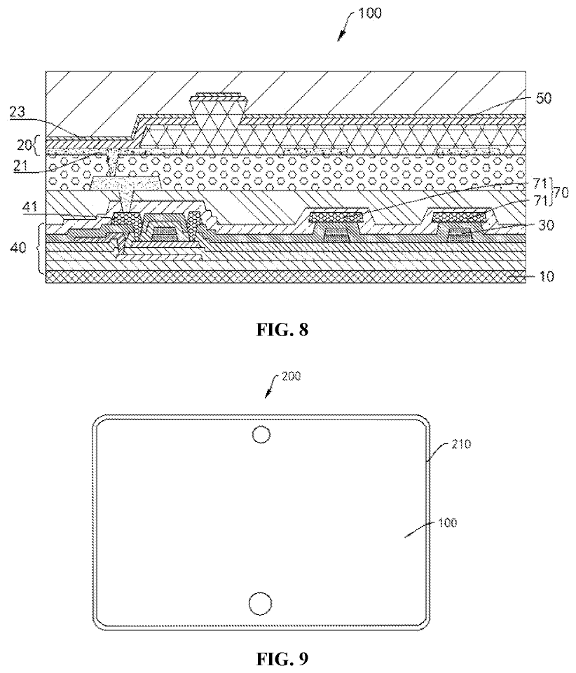

Referring to FIG. 8, in some embodiments, the touch display panel 100 according to the embodiments of the present disclosure includes a drive circuit 40, where the drive circuit 40 is configured to drive the light-emitting unit 20 to emit light. The drive circuit 40 is arranged between the substrate 10 and the multiple touch induction electrodes 50; the drive circuit 40 includes a source/drain electrode 41, and the shielding layer 70 and the source/drain electrode 41 are arranged at a same layer and insulated from each other. Specifically, the shielding layer 70 and the source/drain electrode 41 are formed in a same process, i.e., an entire source/drain electrode layer is prepared first, and then the source/drain electrode layer is patterned by using an etching process to form the source/drain electrode 41 and the shielding layer 70 that are insulated from each other.

Referring to FIG. 4 again, in some embodiments, the touch display panel 100 according to the embodiments of the present disclosure further includes a drive circuit 40 and light-emitting units 20, where the drive circuit 40 and the light-emitting units 20 are stacked between the substrate 10 and the multiple touch induction electrodes 50, and the drive circuit 40 is adjacent to the substrate 10; the light-emitting units 20 each include an anode 21; the drive circuit 40 includes a source/drain electrode 41 and a metal wire 43; the metal wire 43 is located between the source/drain electrode 41 and the anode 21, and the metal wire 43 is electrically connected to the source/drain electrode 41 and the anode 21 respectively; and the shielding layer 70 and the metal wire 43 are arranged at a same layer and insulated from each other. Specifically, the shielding layer 70 and the metal wire 43 are formed in a same process, i.e., an entire metal layer is prepared first, and then the metal layer is patterned by using an etching process to form the metal wire 43 and the shielding layer 70 that are insulated from each other. Specifically, the metal wire 43 may be made of a single metal material or an alloy of multiple metal materials.

Optionally, in some embodiments, an insulating layer 42 and a planarization layer 44 are sequentially stacked on one side of the source/drain electrode 41 that faces away from the substrate 10; the metal wire 43 and the shielding layer 70 are located on a surface of the planarization layer 44 that faces away from the substrate 10; the insulating layer 42 and the planarization layer 44 are provided with a through hole 46 that runs through the insulating layer 42 and the planarization layer 44, and the through hole 46 is filled with a material the same as that of the metal wire 43 to electrically connect the metal wire 43 to the source/drain electrode 41.

Referring to FIG. 3 again, in some embodiments, the shielding layer 70 includes multiple shielding units 71, the multiple shielding units 71 are connected into a whole, and the shielding layer 70 at least partially overlaps with the overlapped regions.

Referring to FIG. 4, FIG. 5 and FIG. 8, in some other embodiments, the shielding layer 70 includes multiple shielding units 71 arranged at intervals, and each of the shielding units 71 at least partially overlaps with at least one of the overlapped regions. Optionally, in some embodiments, the multiple shielding units 71 may be arranged at intervals at a same layer or arranged at different layers, which is not specifically limited in the present disclosure.

Referring to FIG. 9, an embodiment of the present disclosure further provides an electronic device 200, including:

a device body 210; and

the touch display panel 100 according to the embodiment of the present disclosure, where the touch display panel 100 is arranged on the device body 210, and configured to implement display and touch functions.

The electronic device 200 according to the present disclosure includes, but is not limited to, devices with display functions such as a display, a computer, a television, a tablet computer, a mobile phone, an e-reader, a smart watch with a display screen, a smart bracelet and a player with a display screen.

The above are merely specific implementations of the present disclosure, but the protection scope of the present disclosure is not limited thereto. Any person skilled in the art may easily think of various equivalent modifications or replacements within the technical scope disclosed in the present disclosure, and these modifications or replacements should fall within the protection scope of the present disclosure. Therefore, the protection scope of the present disclosure should be subject to the protection scope of the claims.

What is claimed is:

1. A touch display panel, comprising:
a substrate;
multiple display signal lines arranged on one side of the substrate, wherein the display signal lines are configured to provide display signals;
multiple light-emitting units, wherein the multiple light-emitting units are arranged at a same layer and arranged in an array on one side of the display signal lines that faces away from the substrate;
multiple touch induction electrodes, wherein the multiple touch induction electrodes are arranged on one side of the light-emitting units that faces away from the substrate, the touch induction electrodes and the display signal lines are stacked and arranged at intervals, and the multiple touch induction electrodes and the multiple display signal lines have overlapped regions; and
a shielding layer, wherein the shielding layer is located between the touch induction electrodes and the display signal lines, at least a part of the shielding layer is located in the overlapped regions, and the shielding layer is configured to reduce signal interference between the touch induction electrodes and the display signal lines.

2. The touch display panel according to claim 1, wherein the display signal lines comprise at least one of a scanning display signal line and a data display signal line.

3. The touch display panel according to claim 1, wherein the shielding layer is loaded with a constant voltage signal or grounded.

4. The touch display panel according to claim 3, wherein the shielding layer is loaded with a signal the same as that of the touch induction electrode.

5. The touch display panel according to claim 4, further comprising a touch signal line, wherein the touch signal line is electrically connected to the touch induction electrode and the shielding layer respectively.

6. The touch display panel according to claim 1, wherein the light-emitting units each comprise an anode, and the shielding layer and the anode are arranged at intervals at a same layer.

7. The touch display panel according to claim 6, wherein the shielding layer is insulated from the anode, and the shielding layer and the anode are formed in a same process.

8. The touch display panel according to claim 1, wherein the light-emitting units each comprise an anode; and the shielding layer is located between the anode and the display signal line.

9. The touch display panel according to claim 6, wherein the light-emitting units each further comprise a cathode, and the cathode is located between the touch induction electrode and the anode.

10. The touch display panel according to claim 9, further comprising an encapsulation layer, wherein the encapsulation layer is located on one side of the light-emitting units that faces away from the substrate, and the touch induction electrodes each are located on a surface of the encapsulation layer that faces away from the light-emitting unit.

11. The touch display panel according to claim 6, wherein the light-emitting units each further comprise a cathode, the cathode comprises multiple sub-cathodes arranged at intervals, and a gap is formed between adjacent sub-cathodes; the cathode and the touch induction electrodes are arranged at a same layer and insulated from each other; and the touch induction electrode is located in the gap.

12. The touch display panel according to claim 6, wherein the light-emitting units each further comprise a cathode, the cathode comprises multiple sub-cathodes arranged at intervals, and each of the touch induction electrodes is formed by electrically connecting several the sub-cathodes.

13. The touch display panel according to claim 1, further comprising a drive circuit, wherein the drive circuit is arranged between the substrate and the multiple touch induction electrodes; the drive circuit comprises a source/drain electrode, and the shielding layer and the source/drain electrode are arranged at a same layer and insulated from each other.

14. The touch display panel according to claim 1, further comprising a drive circuit, wherein the drive circuit and the light-emitting units are stacked between the substrate and the multiple touch induction electrodes, and the drive circuit is adjacent to the substrate; the light-emitting units each comprise an anode; the drive circuit comprises a source/drain electrode and a metal wire; the metal wire is located between the source/drain electrode and the anode and electrically connected to the source/drain electrode and the anode, respectively; and the shielding layer and the metal wire are arranged at a same layer and insulated from each other.

15. The touch display panel according to claim 14, wherein the shielding layer and the metal wire are formed in a same process.

16. The touch display panel according to claim 14, wherein an insulating layer and a planarization layer are sequentially stacked on one side of the source/drain electrode that faces away from the substrate; the metal wire and the shielding layer are respectively located on a surface of the planarization layer that faces away from the substrate; the insulating layer and the planarization layer are provided with a through hole that runs through the insulating layer and the planarization layer, and the through hole is filled with a material the same as that of the metal wire to electrically connect the metal wire to the source/drain electrode.

17. The touch display panel according to claim 1, wherein the shielding layer comprises multiple shielding units, the multiple shielding units are connected into a whole, and the shielding layer at least partially overlaps with the overlapped regions.

18. The touch display panel according to claim 1, wherein the shielding layer comprises multiple shielding units arranged at intervals, and each of the shielding units at least partially overlaps with at least one of the overlapped regions.

19. The touch display panel according to claim 18, wherein the multiple shielding units are arranged at a same layer or at different layers.

20. An electronic device, comprising:
a device body; and
a touch display panel, wherein the touch display panel is arranged on the device body and configured to implement display and touch functions; and the touch display panel comprises:
a substrate;
multiple display signal lines arranged on one side of the substrate, wherein the display signal lines are configured to provide display signals;
multiple light-emitting units, wherein the multiple light-emitting units are arranged at a same layer and arranged in an array on one side of the display signal lines that faces away from the substrate;
multiple touch induction electrodes, wherein the multiple touch induction electrodes are arranged on one side of the light-emitting units that faces away from the substrate, the touch induction electrodes and the display signal lines are stacked and arranged at intervals, and the multiple touch induction electrodes and the multiple display signal lines have overlapped regions; and
a shielding layer, wherein the shielding layer is located between the touch induction electrodes and the display signal lines, at least a part of the shielding layer is located in the overlapped regions, and the shielding layer is configured to reduce signal interference between the touch induction electrodes and the display signal lines.
